(19) United States
(12) Patent Application Publication
(10) Pub. No.: US 2006/0046363 A1
(43) Pub. Date: Mar. 2, 2006

(54) Process for producing semiconductor device

(75) Inventors: Mitsuo Inoue, Hyogo (JP); Osamu Miyakawa, Hyogo (JP); Takao Sakamoto, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/531,991

(22) PCT Filed: Aug. 31, 2004
(86) PCT No.: PCT/JP04/12537

§ 371 Date: Apr. 20, 2005

(30) Foreign Application Priority Data
Sep. 5, 2003 (JP) 2003-314245

(51) Int. Cl. H01L 21/84

(52) U.S. Cl. 438/166

(57) ABSTRACT

A semiconductor device fabricating method includes forming an amorphous silicon film on a substrate irradiating the amorphous silicon film with laser light to transform at least a part of the amorphous silicon film into a polycrystalline silicon film, and oxidizing the surface of the polycrystalline silicon film in an atmosphere including oxygen, after the irradiation. The laser light is a linear beam having an energy-density gradient of at least 3 (mJ/cm²)/μm in a widthwise direction, and the linear beam is generated by transforming pulsed laser light with a wavelength in a range between 350 nm and 800 nm. The oxidation is performed in a saturated water vapor ambient at a pressure of at least 10 atmospheres and at a temperature in a range between 500° C. and 650° C. With this method, a semiconductor device with excellent crystallinity can be easily fabricated.

### TECHNICAL FIELD

The present invention relates to a method for fabricating a semiconductor device and, more particularly, to a method for fabricating a thin film semiconductor.

### BACKGROUND ART

A polycrystalline silicon thin film transistor formed on an insulating substrate generally has a MOS-FET (Metal Oxide Semiconductor-Field Effect Transistor) structure. A common method for fabricating this thin film transistor is a method which forms a semiconductor layer of polycrystalline silicon on an insulating substrate, then laminates a silicon oxide film as a gate insulating film on the polycrystalline silicon film by a chemical vapor deposition (CVD) method, and further forms a gate electrode thereon. In a polycrystalline thin film transistor fabricated according to this method, there may locally exist crystal defects, impurities and the like on the surface of the polycrystalline silicon which forms the MOS interface. Particularly, if there exist crystal defects and the like in the region between a source region and a drain region formed at portions including the surface of the polycrystalline silicon film, this induces problem of reduction in an electron mobility or a positive hole mobility in this region or rise in a threshold voltage.

Japanese Patent Laying-Open No. 11-67758 discloses a fabricating method including a process for oxidizing a polycrystalline silicon film in an atmosphere mainly consisting of oxygen and providing a low oxidation rate. This fabricating method can cause the surface layer of the polycrystalline silicon film to be slowly oxidized; thereby decreasing crystal defects, making the film quality uniform, and alleviating irregularities on the surface of the polycrystalline silicon film which is left unoxidized. Also, by combining with an oxidation process in an atmosphere mainly consisting of water vapor and providing a high oxidation rate, the rate of oxidation inside the polycrystalline silicon film can be increased and a high-quality semiconductor film including few crystal defects can be formed. Further, when the two processes are performed in an atmosphere under a pressure in a range of 1 to 50 atmospheric pressures and at a temperature in a range of 300 to 700° C., the formation of an oxide film, and the like can be efficiently achieved and damage of the insulating substrate can be prevented. In this prior art, as the method for forming a polycrystalline silicon film, a furnace annealing method (solid phase growth method), a laser annealing method (melting recrystallization method), or the like is employed.

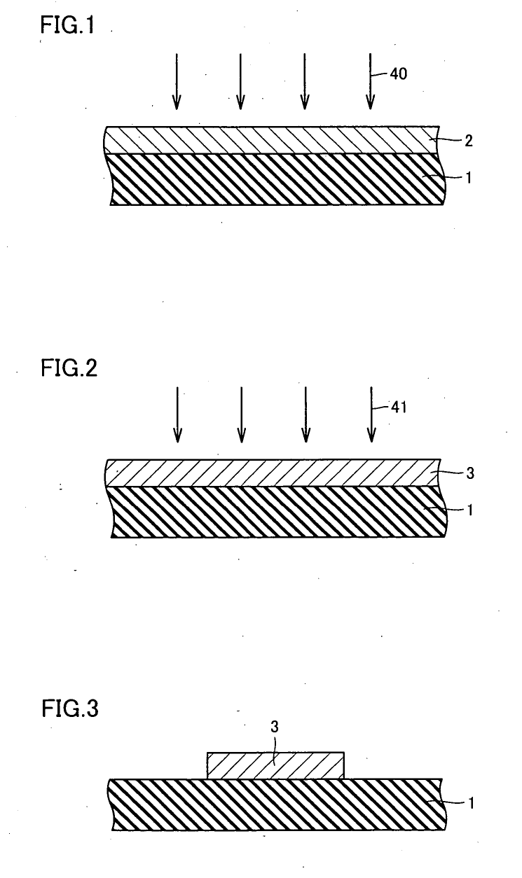

Japanese Patent Laying-Open No. 9-312403 discloses a fabricating method which retains nickel elements in contact with a certain region of an amorphous silicon film. Heat treatment is applied to the amorphous silicon film, on which the nickel elements have been placed, to cause crystal growth in a direction parallel to the substrate. Heat treatment is further applied thereto in an oxidative atmosphere including halogen elements to form a thermal oxide film. Then, a thin film transistor (TFT) is fabricated such that the aforementioned crystal-growth direction is coincident with the direction connecting the source and drain regions. This fabricating method enables to provide a thin film transistor having an excellent mobility and an S-value as transistor characteristics.
Patent Document 1: Japanese Patent Laying-Open No. 11-67758 (pages 3 to 6, FIGS. 1 to 4)
Patent Document 2: Japanese Patent Laying-Open No. 9-312403 (pages 4 to 10, FIGS. 1 to 5)

### DISCLOSURE OF THE INVENTION

Problems to be Solved by the Invention

With the fabricating methods disclosed in Japanese Patent Laying-Open Nos. 11-67758 and 9-312403, the MOS interface can be formed inside the polycrystalline silicon film. This enables to form a MOS interface including few crystal defects and impurities existing on the surface of the polycrystalline silicon, thereby providing a thin film transistor with excellent transistor characteristics.

However, the fabricating method disclosed in Japanese Patent Laying-Open No. 11-67758 employs, in order to form a polycrystalline silicon film, a general method using laser annealing for transforming an amorphous silicon film into a polycrystalline silicon film by irradiating the amorphous silicon film with laser light. With this method, crystal growth in the polycrystalline silicon is caused from the lower side of the molten silicon film, namely, the insulating substrate-side thereof existing at the deepest portion and having a lowest temperature. Since crystal grows from the lower side towards the upper side of the silicon film, namely, towards the surface thereof, the closer to the surface of the silicon, the more favorable crystal will be formed. When the surface of the polycrystalline silicon film is oxidized in order to form a gate insulating film and the like, in the polycrystalline silicon film, the portion having excellent crystallinity will become a silicon oxide film. On the other hand, although the MOS interface at which the source region and the drain region are to be formed is maintained clean, it will be formed at a portion inside the polycrystalline silicon film having poor crystallinity. Since the semiconductor layer is formed at a portion having poor crystallinity in the polycrystalline silicon film, there has been a problem that the performance of the thin film transistor is not sufficiently improved.

The fabricating method in Japanese Patent Laying-Open No. 9-312403 causes crystal growth in a direction parallel to the main surface of the insulating substrate and, then, forms a silicon oxide film by oxidizing the surface of the polycrystalline silicon film. Therefore, it is deemed that there will be no significant variation in the crystallinity along the thickwise direction of the polycrystalline silicon film. Namely, it is deemed that even when the polycrystalline silicon film is oxidized in order to form a silicon oxide film, the left silicon film will have excellent crystallinity. However, in this fabricating method, in order to cause crystal growth in a direction parallel to the main surface of the substrate, it has been necessary that nickel is contained in the silicon film or nickel is removed. Thus, there has been a problem of complexity of the processes. Further, there has been a problem of necessity for fabricating it in a high-temperature atmosphere at about 1000° C.

The present invention was made in order to overcome the aforementioned problems, and aims to provide a semiconductor device fabricating method which can easily fabricate a semiconductor device with excellent crystallinity.

Means for Solving the Problems

A semiconductor device fabricating method based on the present invention includes an amorphous silicon laminating process for forming an amorphous silicon film on a substrate, an irradiation process for irradiating the amorphous silicon film with laser light to transform at least a part of the amorphous silicon film into a polycrystalline silicon film, and an oxidation process for oxidizing the surface of the polycrystalline silicon film in an atmosphere including oxygen after the irradiation process. Herein, the laser light is a linear beam having an energy-density gradient of 3 (mJ/cm²)/μm or more in the widthwise direction, and the linear beam is generated by transforming pulse laser light with a wavelength in a range between 350 nm or more and 800 nm or less. The oxidation process is performed in an atmosphere of saturated water vapor under a pressure of 10 atmospheric pressures or more and at a temperature in a range between 500° C. or more and 650° C. or less.

Effect of the Invention

According to the present invention, a semiconductor device having excellent crystallinity can be easily fabricated.

### BRIEF DESCRIPTION OF THE DRAWINGS

### BRIEF DESCRIPTION OF THE DRAWINGS

FIG. 1 is a cross-sectional view for describing a first step of a semiconductor device fabricating method based on the present invention.

FIG. 2 is a cross-sectional view for describing a second step of the semiconductor device fabricating method based on the present invention.

FIG. 3 is a cross-sectional view for describing a third step of the semiconductor device fabricating method based on the present invention.

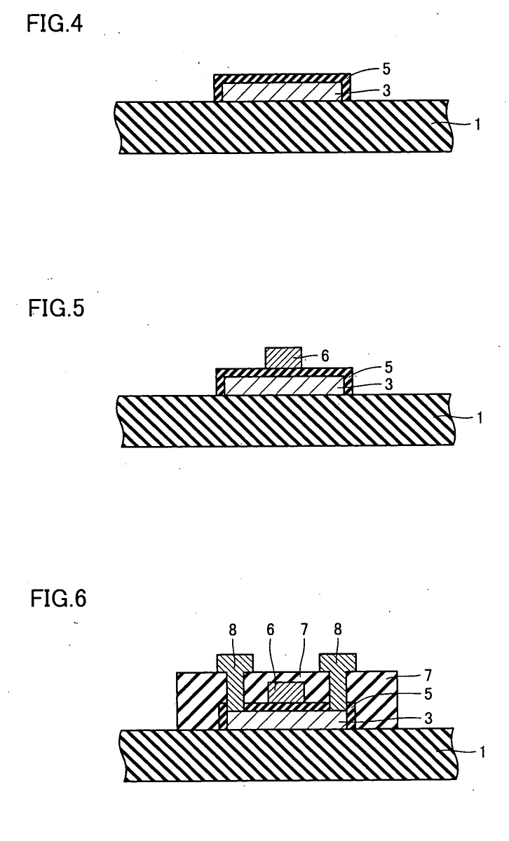

FIG. 4 is a cross-sectional view for describing a fourth step of the semiconductor device fabricating method based on the present invention.

FIG. 5 is a cross-sectional view for describing a fifth step of the semiconductor device fabricating method based on the present invention.

FIG. 6 is a cross-sectional view for describing a sixth step of the semiconductor device fabricating method based on the present invention.

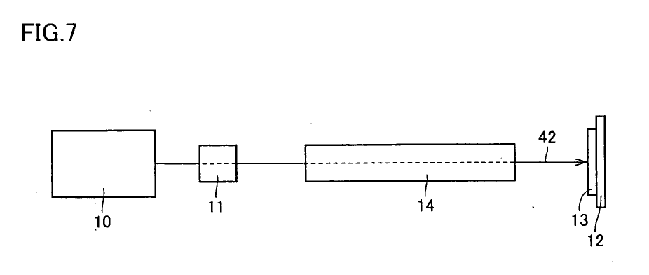

FIG. 7 is a schematic view of a laser-light irradiation device based on the present invention.

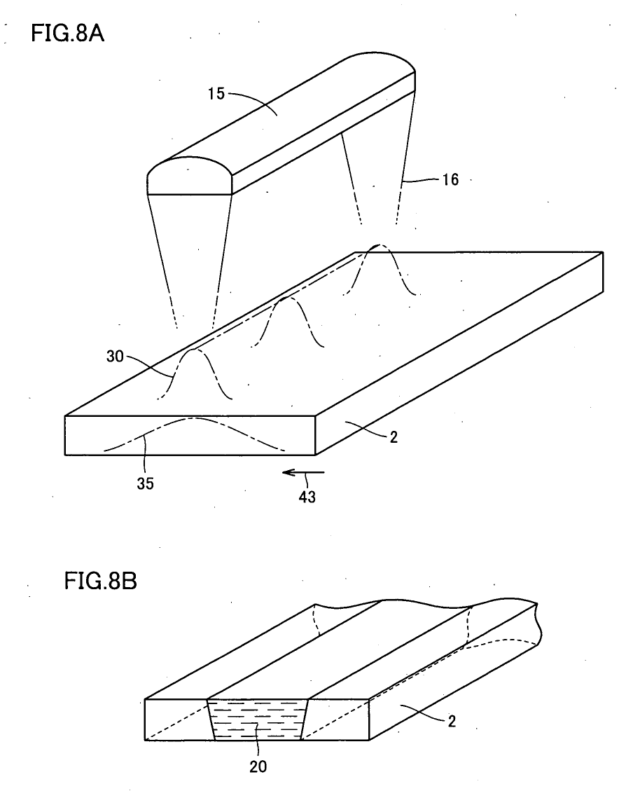

FIG. 8A is a schematic perspective view of laser-light irradiation in the semiconductor device fabricating method based on the present invention.

FIG. 8B is a perspective view for describing an amorphous silicon film being irradiated with laser light in the semiconductor device fabricating method based on the present invention.

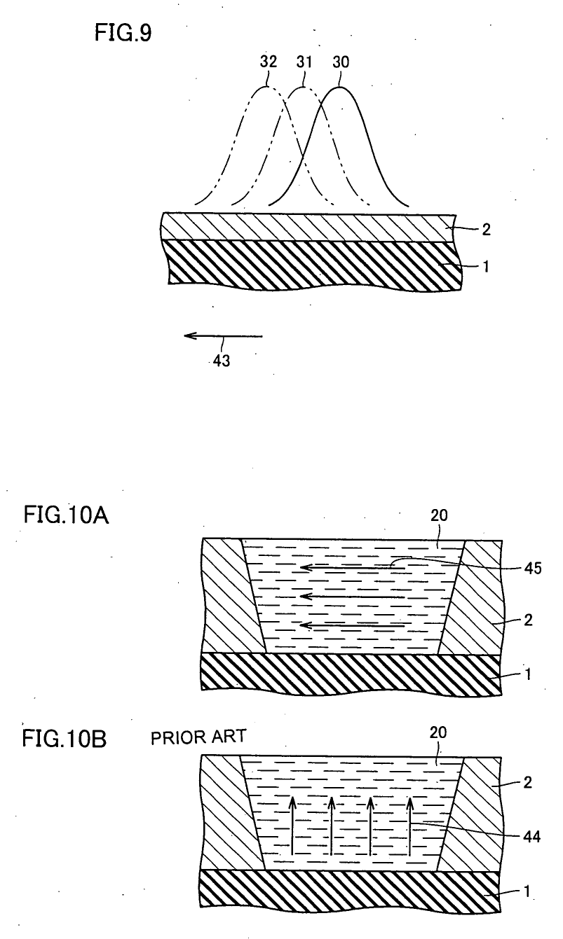

FIG. 9 is an illustration of laser-light irradiation to an amorphous silicon film in the semiconductor device fabricating method based on the present invention.

FIG. 10A is an illustration of the molten portion being crystallized in the semiconductor device fabricating method based on the present invention.

FIG. 10B is an illustration of the molten portion being crystallized in a semiconductor device fabricating method based on the prior art.

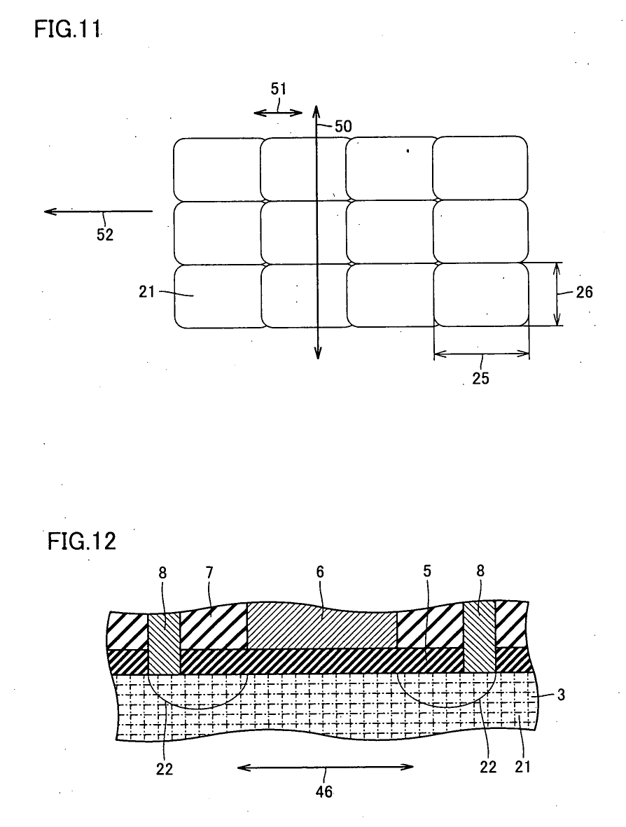

FIG. 11 is a plan view for describing crystal grains in a polycrystalline silicon film formed according to the present invention.

FIG. 12 is an enlarged cross-sectional view of a portion in the vicinity of a MOS interface in a thin film transistor fabricated according to the present invention.

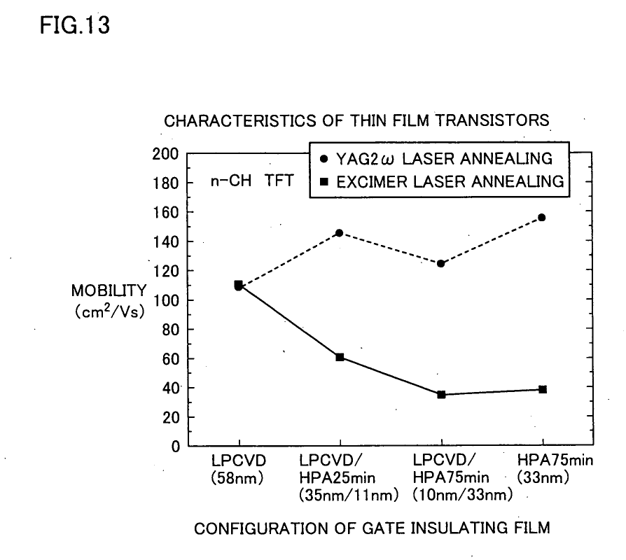

FIG. 13 is a graph for describing the mobility of thin film transistors fabricated according to respective fabricating methods.

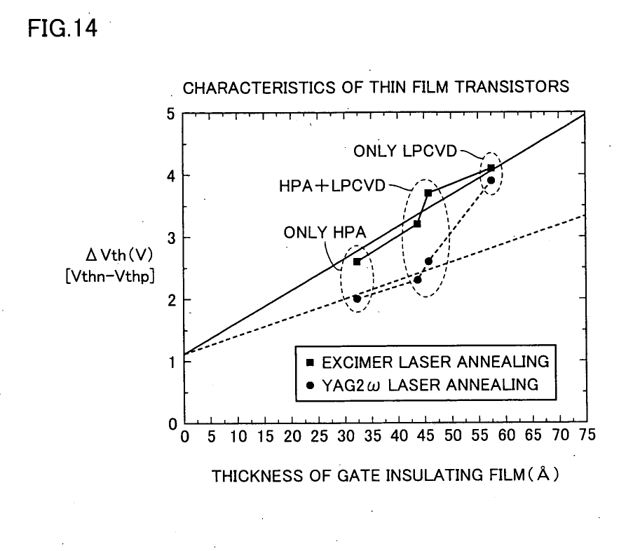

FIG. 14 is a graph for describing the threshold voltages of the thin film transistors fabricated according to respective fabricating methods.

### DESCRIPTION OF SYMBOLS

1: insulating substrate, 2: amorphous silicon film, 3: polycrystalline silicon film, 5: silicon oxide film, 6: gate electrode, 7: protective film, 8: source and drain regions, 10: Nd:YAG laser second harmonic wave lasing device, 11: variable attenuator, 12: movable stage, 13: target, 14: linear-beam shaping optical system, 15: condenser lens, 16: laser light, 20: molten portion, 21: crystal grains, 22: source and drain regions, 25, 26: length, 30, 31, 32: laser-light profile, 35: temperature distribution curve, 40, 41, 42, 43, 44, 45, 46, 50, 51, 52: arrow

### BEST MODES FOR CARRYING OUT THE INVENTION

### First Embodiment

With reference to FIGS. 1 to 14, a semiconductor device fabricating method according to a first embodiment of the present invention will be described.

FIGS. 1 to 6 are cross-sectional views describing an example of a semiconductor device fabricating method based on the present invention. A semiconductor device according to this embodiment is a MOS-FET. FIG. 1 is an illustration of an amorphous silicon laminating process. On the upper surface of an insulating substrate 1, an amorphous silicon film 2 is formed by a CVD method as shown by an arrow 40. As insulating substrate 1, for example, a glass substrate and the like or a silicon oxide film formed as an underlying film on the upper surface of a glass substrate may be employed. In this embodiment, as insulating substrate 1, a silicon oxide film with a thickness of 200 nm formed on the upper surface of a glass substrate by a CVD method is employed. As the material of a film on the substrate, amorphous silicon film 2 is formed by an LPCVD (Low Pressure CVD) method to a thickness of 70 nm.

FIG. 2 is an illustration of an irradiation process. Laser light is applied to the upper surface of amorphous silicon film 2 in the direction of an arrow 41. The laser light irradiation causes amorphous silicon film 2 to be heated and molten. When the molten silicon is cooled and solidified, the crystal structure is changed to a polycrystalline structure; thus, a polycrystalline silicon film 3 is formed.

Next, as shown in FIG. 3, polycrystalline silicon film 3 is patterned into an island shape. FIG. 4 is an illustration of an oxidation process. By placing it in an atmosphere including oxygen, the surface of polycrystalline silicon film 3 is oxidized to form a silicon oxide film 5 which will form a gate insulating film later. Preferably, the oxidation process is performed in an atmosphere of saturated water vapor, as well as in an oxidative atmosphere.

Next, as shown in FIG. 5, a gate electrode 6 is formed on the upper surface of silicon oxide film 5. By these processes, the main portion of the MOS structure is formed. Then, impurities are implanted into the regions of the surface of polycrystalline silicon film 3 which lie at the both sides of gate electrode 6 to form a source region and a drain region. Further, as shown in FIG. 6, a protective film 7 and source and drain electrodes 8 which form extractor electrodes for the source and drain regions are formed around gate electrode 6.

FIG. 7 is an illustration of a laser light irradiation device used in the irradiation process in FIG. 2. As the laser light in this embodiment, the second harmonic wave of an Nd:YAG laser is utilized. The laser light is generated by an Nd:YAG laser second harmonic wave lasing device 10. In this embodiment, the laser light has a wavelength of 532 nm. As shown by an arrow 42, the generated laser light passes through a variable attenuator 11 and a linear-beam shaping optical system 14 and, then, is directed to a target 13 placed on a movable stage 12. The laser light is adjusted to a predetermined intensity by variable attenuator 11 and converted into a linear beam profile by linear-beam shaping optical system 14. Movable stage 12 is configured such that target 13 can be moved relative to the laser light. By using this device, laser heat treatment is applied to target 13.

FIGS. 8A and 8B show schematic views for describing the state of the amorphous silicon film being molten when the amorphous silicon film is irradiated with the laser light. The laser light is converted into linear beam laser light 16 by a condenser lens 15 formed at the output part of the linear-beam shaping optical system (see FIG. 7). Linear laser light 16 is directed to the main surface of amorphous silicon film 2. The distribution of the energy density along the width of the laser light is, for example, the Gaussian distribution. As shown by a laser-light profile 30, the energy density of the condensed laser light is largest at the central portion in the widthwise direction. The energy density gradually decreases with increasing distance outward from the central portion. As laser light 16 used for the irradiation, laser light with an energy-density gradient of at least 3 (mJ/cm²)/m or more in the widthwise direction is employed. The energy density is constant in the longitudinal direction of laser light 16. Thus, the laser light for irradiation has a so-called top-flat shape.

When the second harmonic wave of an Nd:YAG laser is directed to amorphous silicon film 2, amorphous silicon film 2 is heated substantially uniformly in the thickwise direction since amorphous silicon film 2 has a low absorption coefficient with respect to the second harmonic wave. As shown by a temperature distribution curve 35, along the widthwise direction of laser light 16, the portion of amorphous silicon film 2 corresponding to the portion of laser light profile 30 having the largest energy density is heated to a highest temperature, and the temperature gradually decreases along the widthwise direction of laser light 16. Therefore, as shown in FIG. 8B, amorphous silicon film 2 formed on the insulating substrate is molten substantially uniformly in the depthwise direction; thus, a molten portion 20 is formed. In the widthwise direction of laser light 16, only a constant length is molten. In the longitudinal direction of laser light 16, molten portion 20 is formed along the linear beam. Namely, molten portion 20 is formed along the region which corresponds to the portion of laser-light profile 30 having the highest energy density.

FIG. 9 shows an illustration of irradiation of pulse laser light to amorphous silicon film 2. In the irradiation of the laser light, the movable stage is moved; therefore, amorphous silicon film 2 moves together with insulating substrate 1 in the direction of an arrow 43. On the other hand, the position of the irradiation of laser light is fixed. The irradiation of laser light is performed while the movable stage is moved in the widthwise direction of the linear beam. For example, in FIG. 8A, the irradiation of laser light is performed while the movable stage is moved in the direction of arrow 43. In FIG. 9, laser-light profile 30 represents the energy density during a most recent irradiation of laser light. A laser-light profile 31 and a laser-light profile 32 represent energy-density distributions during past laser-light irradiation which have been performed in order. In this irradiation process, the laser light irradiation is performed while the movable stage is shifted by a constant distance at a time in the widthwise direction of the linear beam. If the distance by which it is moved at a time is made larger than the width of the linear beam, the laser light is directed to the same portion only once. On the other hand, if the distance by which it is moved at a time is made smaller than the width of the linear beam, the laser light is directed to the same portion more than once as shown in FIG. 9, thus continuously transforming the amorphous silicon film into a polycrystal. Further, by moving the movable stage during the irradiation of pulse laser light, a certain region of the amorphous silicon film can be entirely transformed into a polycrystalline silicon film.

FIGS. 10A and 10B show cross-sectional views for describing the behavior of the molten silicon being cooled and solidified into a polycrystal. FIG. 10A is an illustration in the case of the irradiation of laser light based on the present invention. As shown in FIG. 8B, amorphous silicon film 2 on the insulating substrate is molten substantially uniformly throughout the thickwise direction. Since there are small temperature differences along the depthwise direction of amorphous silicon film 2 and along the longitudinal direction of the linear beam, crystal grows in the direction of the relative movement of the laser light, namely, in the lateral direction (one-dimensional growth) as shown by an arrow 45. Therefore, the crystal grains grow such that their longitudinal direction is the lateral direction shown by arrow 45, namely, a direction parallel to the main surface of insulating substrate 1. Further, the crystal has no dependence on the depth and a polycrystalline silicon film with excellent crystallinity throughout the entire depth can be obtained.

FIG. 10B shows an illustration of crystal growth in the case of laser-light irradiation based on the prior art. In fabricating methods according to the prior art, laser heat treatment has been performed with a linear beam using an excimer laser (a typical excimer laser is an XeCl laser with a wavelength of 308 nm). In the case of using an excimer laser, amorphous silicon has an extremely large absorption coefficient with respect to the laser light, and most of the laser light is absorbed by an amorphous silicon film in the vicinity of the surface of the amorphous silicon film. Therefore, the temperature is higher near the surface of the amorphous silicon film, while the temperature is lower at lower portions of the amorphous silicon film. Thus, crystal grows in the thickwise direction of the amorphous silicon film. Namely, the laser-light irradiation based on the prior art causes a temperature distribution along the thickwise direction of amorphous silicon film 2; therefore, crystal grows from near the insulating substrate 1 at which the temperature is relatively low towards the opposite side, as shown by an arrow 44. Consequently, the closer to the surface of the amorphous silicon film, the more excellent crystallinity the formed polycrystal will have. However, the portion which will be a MOS interface later exists inside amorphous silicon film 2; therefore, portions with poor crystallinity will form the semiconductor layer. On the contrary, with the fabricating method based on the present invention, it is possible to form favorable crystal grains with crystallinity which has no dependence on the depth in the transformed polycrystalline silicon film as previously described.

Since the widthwise distribution of the condensed beam is, for example, the Gaussian distribution, the energy-density gradient of the laser light applied to the amorphous silicon film varies depending on the position along the width of the laser light as well as on the energy of the laser light. Observations of the shapes of crystal grains in fabricated polycrystalline silicon films were made, and the results of the observations revealed that energy-density gradients of 3 (mJ/cm²)/μm or more cause crystal growth such that the shapes of crystal grains are largely biased in the lateral direction.

FIG. 11 shows a plan view of crystal grains in the case there has been significant lateral growth. The direction shown by an arrow 50 is the longitudinal direction of the linear beam and the direction shown by an arrow 51 is the widthwise direction of the linear beam. The laser light is applied to the amorphous silicon film while being moved relative thereto in the direction shown by an arrow 52. Individual crystal grains 21 grow in the lateral direction, namely, in the direction of arrow 51. In this embodiment, there were obtained large crystal grains with grain sizes of about a few μm. More specifically, there were obtained crystal rows of polycrystalline silicon in which length 25 in the lateral direction, which is the growth direction of crystal grains 21, is twice or more length 26 perpendicular to the growth direction and the longitudinal direction of crystal grains 21 is parallel to the widthwise direction of the linear beam (the direction of movement of the movable stage). By forming such a crystal, a semiconductor film having a large electron mobility or positive hole mobility can be provided. Particularly, a semiconductor film having a large mobility in the longitudinal direction of crystal grains 21 can be provided.

The surface of a polycrystalline silicon film formed according to the aforementioned fabricating method was oxidized in an atmosphere of saturated water vapor under a pressure of 20 atmospheric pressures (2.026 MPa) and at a temperature of 600° C. to form an gate insulating film; thus, a thin-film transistor was fabricated. In this specification, the method for forming a silicon oxide film by oxidizing the surface of a polycrystalline silicon film in an atmosphere of saturated water vapor is referred to as an “HPA method”.

FIG. 12 shows an enlarged cross-sectional view of a portion around the MOS interface in a MOS-FET fabricated according to the semiconductor device fabricating method based on the present invention. A silicon oxide film 5 is formed under a gate electrode 6 and, further, a polycrystalline silicon film 3 is formed thereunder. In FIG. 12, there are schematically shown crystal grains 21 which have been grown inside polycrystalline silicon film 3. On the upper surface of polycrystalline silicon film 3, source and drain regions 22 are formed at the sides of the regions which will be in shade when gate electrode 6 is projected onto polycrystalline silicon film 3. Source and drain regions 22 are formed at both the right and left sides. There are formed, at the sides of gate electrode 6, source and drain electrodes 8 for establishing conduction with source and drain regions 22. In the irradiation process for the thin-film transistor, irradiation is performed while the movable stage is moved such that the direction of movement of the movable stage (the widthwise direction of the linear beam) is parallel to the direction connecting the source region and the drain region, as shown by an arrow 46. Therefore, the crystal grains have been grown such that the longitudinal direction of the crystal grains is parallel to the direction connecting the source region and the drain region shown by arrow 46. Further, there is no irregularity in the crystal grains along the thickwise direction of polycrystalline silicon film 3, and the crystal grains of the polycrystalline silicon film which has been formed have substantially uniform shapes. When the MOS-FET is being driven, electrons or positive holes move between the source and drain regions 22 in the direction shown by arrow 46.

FIG. 13 shows a graph for making comparison between n-channel thin-film transistors fabricated according to the fabricating method based on the prior art and n-channel thin-film transistors fabricated according to the fabricating method based on the present invention, in terms of the mobility out of the electric characteristics. The fabricating method based on the prior art was a method for forming polycrystalline silicon using an excimer laser in the irradiation process. The horizontal axis represents methods for forming the gate electrode and the thicknesses formed by the respective methods. The vertical axis represents the mobilities of thin-film transistors fabricated according to the respective fabricating methods. The rightmost points along the horizontal axis designate thin-film transistors including a silicon oxide film formed only by the HPA method. It can be seen that the fabricating method according to this embodiment (a method using YAG2ω laser annealing) provides higher mobilities than those achieved by the fabricating method based on the prior art (a method using an excimer laser annealing).

FIG. 14 shows a graph for making comparison between thin-film transistors fabricated according to the fabricating method based on the prior art and thin-film transistors fabricated according to the fabricating method based on the present invention, in terms of the threshold voltage out of the electric characteristics. The horizontal axis represents the thicknesses of the gate insulating films which were formed therein and the vertical axis represents the threshold voltages. The respective fabricating methods are the same as the fabricating methods shown in FIG. 13. The leftmost points along the horizontal axis represent the thin-film transistors including a silicon oxide film formed only by HPA method. It can be seen that the fabricating method according to this embodiment (a method using YAG2ω laser annealing) provides threshold voltages lower than those provided by the fabricating method based on the prior art (a method using an excimer laser annealing).

As described above, the adoption of the semiconductor fabricating method according to this embodiment can provide a thin-film transistor having a high mobility. Further, a thin-film transistor having a low threshold voltage can be provided. It is supposed that these effects are attributable to the favorable shapes and sizes of the crystal grains caused by the difference in the crystal-growth direction as previously described. Particularly, it is considered possible to fabricate a high-performance thin-film transistor in which the region sandwiched between the source region and the drain region includes less grain boundaries and thus has a high mobility, since the longitudinal direction of the crystal grains is parallel to the direction from the source region to the drain region. As described above, the fabricating method based on the present invention can provide a semiconductor device having excellent transistor characteristics.

### Second Embodiment

With reference to FIGS. 13 and 14, a semiconductor device fabricating method based on a second embodiment of the present invention will be described.

In this embodiment, similarly to the first embodiment, a polycrystalline silicon film was formed by using a second harmonic wave lasing device of an Nd:YAG laser with a wavelength of 532 nm as the laser lasing device. Subsequently, as the oxidation process, at first, the surface of the polycrystalline silicon film was oxidized in an atmosphere of saturated water vapor under a pressure of 20 atmospheric pressures and at a temperature of 500° C. to form a silicon oxide film.

Under this oxidation condition, a prolonged process is required in order to provide an oxide film with a predetermined thickness. Therefore, as a first semiconductor device in this embodiment, the surface of the polycrystalline silicon was oxidized to a thickness of only 11 nm and, then, a silicon oxide film with a thickness of 35 nm was laminated thereon by an LPCVD method to provide a predetermined thickness. An n-channel thin-film transistor employing this silicon oxide film as a gate insulating film was fabricated. Next, as a second semiconductor device in this embodiment, the surface of the polycrystalline silicon film was oxidized to form an oxide film with a thickness of 33 nm and, then, a silicon oxide film with a thickness of 10 nm was laminated thereon by an LPCVD method. An n-channel thin-film transistor employing this silicon oxide film as a gate insulating film was fabricated. Further, a thin-film transistor employing a silicon oxide film formed only by an LPCVD method was fabricated. Further, for these fabricating methods, thin-film transistors were fabricated by using an excimer laser based on the prior art in the irradiation process for forming a polycrystalline silicon film. For the thin-film transistors fabricated according to the respective fabricating methods, measurements of electric characteristics were performed in order to investigate the transistor characteristics. The results are described in FIGS. 13 and 14.

FIG. 13 shows the mobilities of the respective semiconductor devices. The horizontal axis in FIG. 13 represents the configurations of the gate insulating films, and represents, in order from the left, the thin-film transistors including the silicon oxide film with a thickness of 58 nm formed by the LPCVD method, the thin-film transistors including the silicon oxide film which was formed to a thickness of 11 nm by performing the HPA method for 25 minutes and then laminated by a thickness of 35 nm thereon by the LPCVD method, the thin-film transistors including the silicon oxide film which was formed to a thickness of 33 nm by performing HPA method for 75 minutes and then laminated by a thickness of 10 nm thereon by the LPCVD method, and the thin-film transistors including the silicon oxide film with a thickness of 33 nm which was laminated by performing only HPA method for 75 minutes.

As a result, when the laser annealing based on the present invention was performed, the thin-film transistors including the silicon oxide film formed by combining the HPA method and the LPCVD method could have performance similar to that of the thin-film transistor including the silicon oxide film formed only by the HPA method. Further, with the fabricating method based on the prior art (fabricating method using an excimer laser annealing), the mobility tended to decrease with increasing use of the HPA method, namely, with increasing use of the method for oxidizing the polycrystalline silicon surface. On the other hand, with the fabricating method based on the present invention (the method using YAG2ω laser annealing), no reduction in the mobility was observed even when the HPA method was largely used, so that a thin film transistor with large mobility can be provided.

FIG. 14 is a graph showing the threshold voltages of the respective semiconductor devices. The horizontal axis represents the thicknesses of the gate insulating films, and the vertical axis represents the threshold voltages. It can be seen that the fabricating method based on the present invention provided lower threshold voltages as compared with the fabricating method based on the prior art, regardless of the fabricating method using only the HPA method, the LPCVD method and the HPA method, or only the LPCVD method. In focusing attention on the fabricating methods including the HPA method and even in consideration of the thickness dependence, it can be seen that the fabricating method based on the present invention provided lower threshold voltages, which deviate from the line indicating the dependence on the thickness of the gate insulating film in the semiconductor devices fabricated using the prior-art excimer laser, as shown by a dot line

Further, measurements of the breakdown strengths, namely, the withstand voltages were performed by maintaining the source region and the drain region at the same potential and applying a voltage between these regions and the gate electrode. As a result, it was revealed that the thin-film transistors fabricated by combining the HPA method and the LPCVD method had higher withstand voltages than those of the thin-film transistors fabricated by oxidizing the surface of the polycrystalline silicon film to a thickness of 33 nm. As described above, by forming a silicon oxide film as a gate insulating film using the HPA method and an LPCVD method, a thin-film transistor with a high withstand voltage can be provided.

As described in this embodiment, by laminating silicon oxide by a chemical vapor deposition method after the oxidation process for oxidizing the surface of the polycrystalline silicon film in an atmosphere including water vapor, the MOS interface can be maintained clean and a silicon oxide film with a required thickness can be formed in a short time period.

### Third Embodiment

In a third embodiment based on the present invention, laser light is applied to an amorphous silicon film using a third harmonic wave lasing device of an Nd:YAG laser, instead of a second harmonic wave lasing device of an Nd:YAG laser in the irradiation process in the first embodiment. The third harmonic wave lasing device generates laser light with a wavelength of 355 nm. The configurations other than the laser light for irradiation, such as the optical system for the laser light and the movement of the insulating substrate and the amorphous silicon film during the irradiation of laser light, are the same as those in the first embodiment.

As a result of applying laser annealing to the amorphous silicon film, lateral growth in the widthwise direction of the linear beam was observed similarly to in the first embodiment in which laser light with a wavelength of 532 nm was applied. Further, there were formed crystal grains having large grain sizes of about a few μm.

The surface of the polycrystalline silicon film was oxidized in an atmosphere of saturated water vapor under a pressure of 20 atmospheric pressures and at a temperature of 600° C. to form a gate insulating film. A thin-film transistor including the gate insulating film was fabricated and subjected to performance tests. This thin-film transistor could provide excellent performance, similarly to the thin-film transistor according to the first embodiment which was fabricated by applying laser light with a wavelength of 532 nm.

From this embodiment and the first embodiment, it can be said that when the generated laser light has a wavelength in a range between 355 nm or more and 532 nm or less, laterally-grown crystal grains can be obtained and further a thin-film transistor with excellent performance can be provided.

### Fourth Embodiment

In a fourth embodiment based on the present invention, a Ti:Sapphire laser lasing device was employed, instead of a second harmonic wave lasing device of an Nd:YAG laser in the irradiation process of the first embodiment. This laser lasing device is a wavelength-variable lasing device and can generate laser light with a wavelength in a range of 700 nm to 800 nm. The configurations other than the laser light for irradiation, such as the optical system for the laser light and the movement of the insulating substrate and the amorphous silicon film during the irradiation of laser light, are the same as those in the first embodiment.

As a result of applying laser annealing to the amorphous silicon film, lateral growth in the widthwise direction of the linear beam was observed for any wavelength. Further, there were formed crystal grains having large grain sizes of about a few μm.

The surface of the polycrystalline silicon film was oxidized in an atmosphere of saturated water vapor under a pressure of 20 atmospheric pressures and at a temperature of 600° C. to form a gate insulating film. Then, a thin-film transistor including the gate insulating film was fabricated and subjected to performance tests. This thin-film transistor could provide excellent performance, similarly to the thin-film transistor according to the first embodiment which was fabricated by applying laser light with a wavelength of 532 nm.

From this embodiment and the first embodiment, it can be said that when the generated laser light has a wavelength in at least a range between 532 nm or more and 800 nm or less, laterally-grown crystal grains can be obtained and, further, a thin-film transistor with excellent performance can be provided. Further, from the fact that there were not observed lateral growth in the case of using an excimer laser (for example, an XeCl laser with a wavelength of 308 nm) in the prior art and from the results of the third embodiment and this embodiment, it can be said that when the generated laser light has a wavelength in a range between 350 nm or more and 800 nm or less, laterally-grown crystal grains can be obtained and, further, a thin-film transistor with excellent performance can be provided.

### Fifth Embodiment

In a fifth embodiment of the present invention, similarly to the first embodiment, a second harmonic wave lasing device of an Nd:YAG laser with a wavelength of 532 nm was employed to form a polycrystalline silicon film and, subsequently, in the oxidation process, a gate insulating film was formed by oxidizing the surface of the polycrystalline silicon film in an atmosphere of saturated water vapor under a pressure of 20 atmospheric pressures and at a temperature of 500° C.

As a result, the growth rate of the oxide film was significantly reduced as compared with the case of the oxidation condition of the first embodiment in which the temperature is 600° C. and the pressure is 20 atmospheric pressures, thereby increasing the processing time required for providing a gate insulating film with a predetermined thickness. Therefore, it is more preferable that the oxidation process for oxidizing the surface of the polycrystalline silicon film in an atmosphere including water vapor is performed at a temperature of 600° C. or more. On the other hand, a thin-film transistor having performance similar to that of the thin-film transistor in the first embodiment could be provided.

From this embodiment, it can be said that a thin-film transistor with excellent performance can be provided by setting the temperature in the oxidation process to a temperature in a range between 500° C. or more and 600° C. or less.

### Sixth Embodiment

In a sixth embodiment of the present invention, similarly to the first embodiment, a second harmonic wave lasing device of an Nd:YAG laser with a wavelength of 532 nm was employed to form a polycrystalline silicon film and, subsequently, in the oxidation process, a gate insulating film was formed by oxidizing the surface of the polycrystalline silicon film in an atmosphere of saturated water vapor under a pressure of 10 atmospheric pressures (1.013 MPa) and at a temperature of 650° C.

A thin-film transistor fabricated according to this method had performance similar to that of the thin-film transistor fabricated under the laser-annealing condition of the first embodiment in which the temperature was 600° C. and the pressure was 20 atmospheric pressures. On the other hand, when the temperature was set to above 650° C., the thermal contraction in the insulating substrate was increased, thereby causing defects in patterning during the thin-film transistor fabrication processes. Therefore, it was difficult to fabricate a proper transistor. From the results of the fifth embodiment and this embodiment, it is preferable that the temperature in the oxidation process is in a range between 500° C. or more and 650° C. or less.

From the results of the first embodiment and third to sixth embodiments, it is preferable that the oxidation process for oxidizing the surface of the polycrystalline silicon film in an atmosphere including water vapor is performed in an atmosphere of saturated water vapor under a pressure of 10 atmospheric pressures or more and at a temperature in a range between 500° C. or more and 650° C. or less. By oxidizing the polycrystalline silicon film under this condition, a silicon oxide film with a predetermined thickness can be formed in a short time period and a dense silicon oxide film can be formed. Further, thin-film transistors having low threshold voltages can be fabricated with high productivity.

The aforementioned embodiments which have been described are illustrative and not limitative in all points. The scope of the present invention is defined by claims and not by the above description, and includes all meanings equivalent to the claims and variations within the claims.

### INDUSTRIAL APPLICABILITY

The present invention can be applied to methods for fabricating semiconductor devices. Particularly, the present invention can be advantageously applied to methods for fabricating thin-film semiconductors.

1. A semiconductor device fabricating method comprising:
an amorphous silicon laminating process for forming an amorphous silicon film on a substrate;
an irradiation process for irradiating said amorphous silicon film with laser light to transform at least a part of said amorphous silicon film into a polycrystalline silicon film; and
an oxidation process for oxidizing the surface of said polycrystalline silicon film in an atmosphere including oxygen, after said irradiation process, wherein
said laser light is a linear beam having an energy-density gradient of 3 (mJ/cm²)/μm or more in the widthwise direction, and said linear beam is generated by transforming pulse laser light with a wavelength in a range between 350 nm or more and 800 nm or less, and
said oxidation process is performed in an atmosphere of saturated water vapor under a pressure of 10 atmospheric pressures or more and at a temperature in a range between 500° C. or more and 650° C. or less.

2. The semiconductor device fabricating method according to claim 1, comprising a process for further laminating silicon oxide, by a chemical vapor deposition method, on the upper surface of said polycrystalline silicon film which has been oxidized in said oxidation process.

3. The semiconductor device fabricating method according to claim 1, wherein, in said irradiation process, said amorphous silicon film is irradiated with said laser light such that said widthwise direction is parallel to the direction connecting a source region and a drain region in a thin film transistor to be fabricated.

4. The semiconductor device fabricating method according to claim 2, wherein, in said irradiation process, said amorphous silicon film is irradiated with said laser light such that said widthwise direction is parallel to the direction connecting a source region and a drain region in a thin film transistor to be fabricated.

5. A method of fabricating a semiconductor device, the method comprising:
forming an amorphous silicon film on a substrate;
irradiating said amorphous silicon film with laser light to transform at least a part of said amorphous silicon film into a polycrystalline silicon film; and
oxidizing said polycrystalline silicon film in an ambient including oxygen, after the irradiation, wherein
the laser light is a linear beam having an energy-density gradient of at least 3 (mJ/cm²)/μm in a widthwise direction, and including generating the linear beam by transforming pulsed laser light having a wavelength in a range between 350 nm and 800 nm, and
the oxidizing is performed in a saturated water vapor ambient at a pressure of at least 10 atmospheres and at a temperature in a range between 500° C. and 650° C.

6. The method according to claim 5, comprising depositing a film of silicon oxide, by chemical vapor deposition, on said polycrystalline silicon film after the oxidizing.

7. The method according to claim 5, including irradiating said amorphous silicon film with the laser light so that the widthwise direction is parallel to a direction connecting a source region and a drain region in a thin film transistor to be fabricated in the polycrystalline silicon film.

8. The method according to claim 6, including irradiating said amorphous silicon film with the laser light so that the widthwise direction is parallel to a direction connecting a source region and a drain region in a thin film transistor to be fabricated in the polycrystalline silicon film.
